(19) United States
(12) Patent Application Publication
(10) Pub. No.: US 2026/0271675 A1
(43) Pub. Date: Sep. 10, 2026

(54) DIE-LEVEL WARP CONTROL IN DEVICE MANUFACTURING

(71) Applicant: Applied Materials, Inc., Santa Clara, CA (US)

(72) Inventors: Changwoo Sun, Dublin, CA (US); Pradeep Kumar Subrahmanyan, San Jose, CA (US)

(21) Appl. No.: 19/254,493

(22) Filed: Jun. 30, 2025

Related U.S. Application Data
(60) Provisional application No. 63/769,297, filed on Mar. 10, 2025.

(51) Int. Cl. H01L 21/66; H01L 21/67; H01L 21/78; H01L 23/00

(52) U.S. Cl. CPC H10P 74/203; H10P 54/00; H10P 72/0616; H10W 42/121

(57) ABSTRACT

Disclosed systems and techniques are directed to optimization of semiconductor manufacturing by forming a product including a plurality of features supported by one or more substrates, determining a deformation profile of the product, determining, using the deformation profile, a distribution of local curvatures of the product. The techniques further include forming a stress-compensation layer (SCL) on the product, one or more properties of the SCL determined to reduce the mean of the distribution of the local curvatures of the product, and irradiating the SCL with a stress-modulation beam, a local dose of the stress-modulation beam determined to reduce the width of the distribution of the local curvatures of the product.

### RELATED APPLICATIONS

This application claims the benefit of the U.S. Provisional Patent Application No. 63/769,297, entitled “DIE WARP CORRECTION TO CONTROL DIE LEVEL WARP FOR HIGH BANDWIDTH MEMORY (HBM) MANUFACTURING,” filed Mar. 10, 2025, the entire contents of which are being incorporated in their entirety by reference herein.

### TECHNICAL FIELD

The disclosure pertains to semiconductor manufacturing, including processing of wafers and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### BRIEF DESCRIPTION OF THE DRAWINGS

The present disclosure will be understood more fully from the detailed description given below and from the accompanying drawings of various embodiments of the disclosure.

FIG. 1 illustrates schematically stresses in an example wafer structure that can be mitigated using the techniques of the instant disclosure.

FIGS. 2A-2H illustrate an example semiconductor die manufacturing process, according to at least one embodiment.

FIGS. 3A-3M illustrate a process of die semiconductor manufacturing that deploys stress-compensation layers and stress-modification beams for local die wrap correction, according to at least one embodiment.

FIGS. 4A-4E illustrate schematically a process of correcting a product deformation using a stress-modulation beam applied to the product, according to at least one embodiment.

FIG. 5 illustrates an example Zernike polynomial decomposition of one actual deformation (top left) of a wafer, in arbitrary units, into a paraboloid bow deformation (top right), a saddle deformation (bottom left), and a residual deformation, (bottom right), according to at least one embodiment.

FIGS. 6A-6D are schematic illustrations of a die-level control of warp as part of semiconductor manufacturing, in accordance with at least one embodiment.

FIG. 7 is a flowchart illustrating an example method of deploying stress-compensation layers and stress-modification beams for local die wrap correction, in accordance with at least one embodiment.

FIG. 8 is a flowchart illustrating an example method of determining settings for beam irradiation, in accordance with at least one embodiment.

FIGS. 9A-9B illustrates schematically an irradiation system capable of performing irradiation of stress compensation layers, according to at least one embodiment.

FIG. 10 depicts a block diagram of an example computer system capable of supporting operations of the present disclosure, according to at least one embodiment.

### SUMMARY

Disclosed herein, according to one embodiment, is a method that includes forming a product comprising a plurality of features supported by one or more substrates, determining a deformation profile of the product, determining, using the deformation profile, a distribution of local curvatures of the product, and forming a stress-compensation layer (SCL) on the product. Properties of the SCL are determined to reduce a mean of the distribution of the local curvatures of the product. The method further includes irradiating the SCL with a stress-modulation beam. A local dose of the stress-modulation beam is determined to reduce a width of the distribution of the local curvatures of the product.

In another embodiment, disclosed is a system that includes a memory device and a processing device communicatively coupled to the memory device. The processing device causes performance of operations that include forming a product comprising a plurality of features supported by one or more substrates, determining a deformation profile of the product, determining, using the deformation profile, a distribution of local curvatures of the product, and forming an SCL on the product. Properties of the SCL are determined to reduce a mean of the distribution of the local curvatures of the product. The operations further include irradiating the SCL with a stress-modulation beam, a local dose of the stress-modulation beam determined to reduce a width of the distribution of the local curvatures of the product.

In yet another embodiment, disclosed is a semiconductor manufacturing system that includes one or more processing chambers, to form a product comprising a plurality of features supported by one or more substrates, determine a deformation profile of the product, determine, using the deformation profile, a distribution of local curvatures of the product, and form an SCL on the product. Properties of the SCL determined to reduce a mean of the distribution of the local curvatures of the product. The semiconductor manufacturing system is further to irradiate the SCL with a stress-modulation beam, a local dose of the stress-modulation beam determined to reduce a width of the distribution of the local curvatures of the product.

### DETAILED DESCRIPTION

Modern technology often aims to maximize chip area utilization by manufacturing three-dimensional devices having multiple layers of semiconducting structures. For example, in high-bandwidth (HBW) dynamic random access memory (DRAM) devices, multiple DRAM chips can be stacked in a vertical arrangement with through-silicon via (TSV) connections passing through the stack of DRAM chips. Vertical stacking can include, e.g., stacking of logic circuitry on memory circuitry or other logic circuitry, placing interposer circuitry (interconnects) between vertically stacked dies or chips, and/or the like. Such vertical stacking can be accomplished using various hybrid bonding (or bump bonding) techniques, including bonding a first wafer supporting first features (e.g., logic/memory/circuitry) deposited thereon—to a second wafer (the wafer-to-wafer bonding process) that supports second features, aligning these second features with the first features, and then transferring the second features to the first wafer (while removing the second wafer). In other instances, one or multiple individual dies can be picked up (by a suitable end effector) from the second wafer and transferred to the first wafer by placing those individual dies in locations that accurately match locations of dies of the first wafer (the die-to-wafer bonding process). Prior to or after such feature stacking, the second wafer can be thinned (e.g., dissolved, grinded, etched, and/or polished) to expose—through the back side of the second wafer—the second features to further operations (e.g., placement of additional circuitry, dies, and/or the like). Subsequently, the aligned/transferred features and the first/second wafer can be cut into individual devices, e.g., dies or chips.

Deposition of various films and circuitry on wafers typically leads to stresses and deformation of the wafers. Such stresses result from a direct mechanical (elastic) interaction between wafers and films/circuitry, a mismatch of thermal expansion coefficients of wafer/film/conductor materials, and/or the like. Additional stress and deformation of the wafers are caused by the wafer thinning and cutting of the deposited features, and/or other processing operations (e.g., protective film/mask deposition, etc.) More specifically, thinning of the wafer leaves less material support available for anchoring (holding in place) the deposited films (and/or other features), which are subject to stresses that built up during the deposition process. As the wafer is thinned, the stress in these deposited films (and/or other features) remains largely the same and is transferred (through thinner remnants of the wafer) to the dies causing the dies and the wafer hosting the dies to deform (e.g., warp).

Die/wafer deformation can lead to misalignment of manufactured features and can result in substandard or inoperable devices, including cracking of dies, delamination of dies, dies that fail to adhere to substrates, dies that display inconsistent electrical contacts, dies having mismatched circuitry, and/or the like. Correcting die/wafer deformation is, therefore, important for die/device quality. Furthermore, after a wafer with deposited features is cut into dies, distribution of stresses can change significantly and may result in warping (curving) of individual dies, which can differ significantly by magnitude and even sign. Specifically, local stresses of different magnitudes and/or opposite signs (that largely cancel out by abutting dies while the dies still remain together attached to a wafer) are released causing deformation of the dies. When dies with different degrees and/or signs of warps are stacked, adherence of such dies to each other can be compromised, causing fatal device failures, e.g., delaminations, misalignment of features, and/or the like. This local die-level variation of stresses makes stress mitigation particularly challenging.

Aspects and embodiments of the present disclosure address these and other challenges of the modern semiconductor manufacturing technology by providing for systems and techniques capable of correcting die-to-die variations in warping to facilitate stronger and more accurate bonding. In one example embodiment, die manufacturing can include multiple operations. More specifically, a set of features (e.g., transistors, interconnect circuitry, and/or the like) can be deposited or otherwise formed on a first substrate (e.g., silicon wafer). An adhesive layer may be formed on a second substrate (e.g., a glass wafer, silicon wafer) and used to bind to the features forming a structure (also referred to as a “product” herein) in which the features are enclosed between the two substrates. The first substrate can then undergo thinning (on its backside) until the features (or a portion of the features) are exposed through the backside. Such operations can cause the product to experience stress, both global deformations (e.g., parabolic bow, cylindrical, saddle-shaped, etc.) and local deformations (e.g., from die-to-die variations of stress). To correct such deformations, an optical inspection can be performed to determine a deformation profile of the product. A distribution of local (e.g., in reference to a grid of die-sized cells) curvatures of the product can then be determined. A stress-compensation layer (SCL) can be formed on the product with various properties of the SCL (e.g., material, thickness, stress, etc.) determined to decrease the mean of the distribution of the local curvatures). As such, the SCL corrects a global deformation of the product and the deposited features. The SCL can be formed at relatively low temperatures, e.g., 140-160 degrees Celsius to reduce leakage current in devices that are to be manufactured from the product. The SCL can be further irradiated with a suitable stress-modulation beam of particles (e.g., ions, electrons) or photons to modify local stresses in the SCL and, therefore, the product. The local irradiation doses can be determined to decrease the width of the distribution of the local curvatures of the product. As such, the stress-modulation beam causes correction of local (e.g., die-scale) stresses in the product so that when the product is cut into individual dies, the deformation of the dies is reduced significantly compared with conventional techniques.

The disclosed embodiments can be applied to correcting warping of any “wafer” or “substrate,” which refers to any material capable of supporting one or more films, masks, photoresists, layers, etc., that are deposited, formed, etched, or otherwise processed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

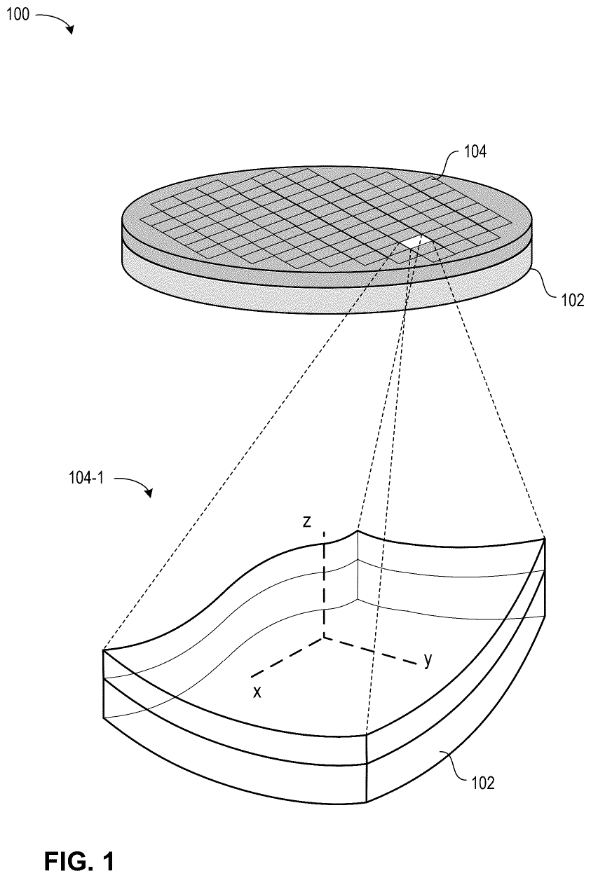

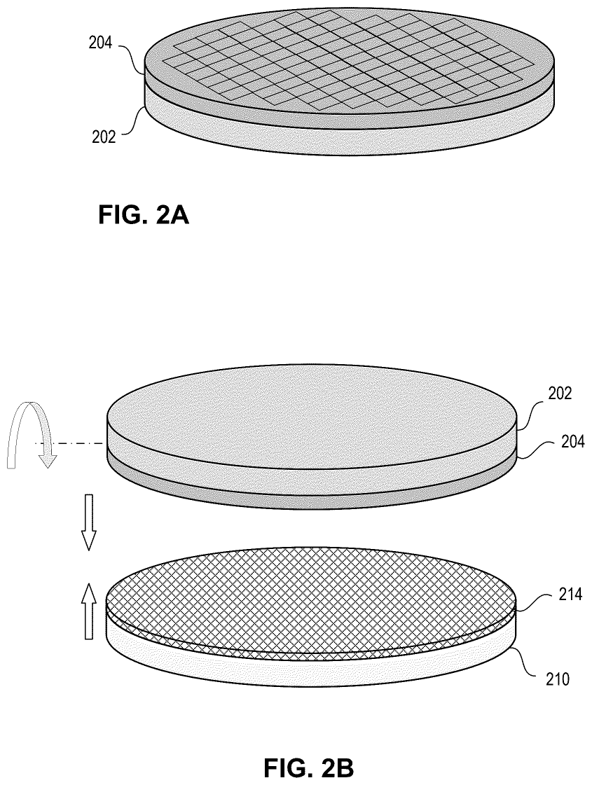

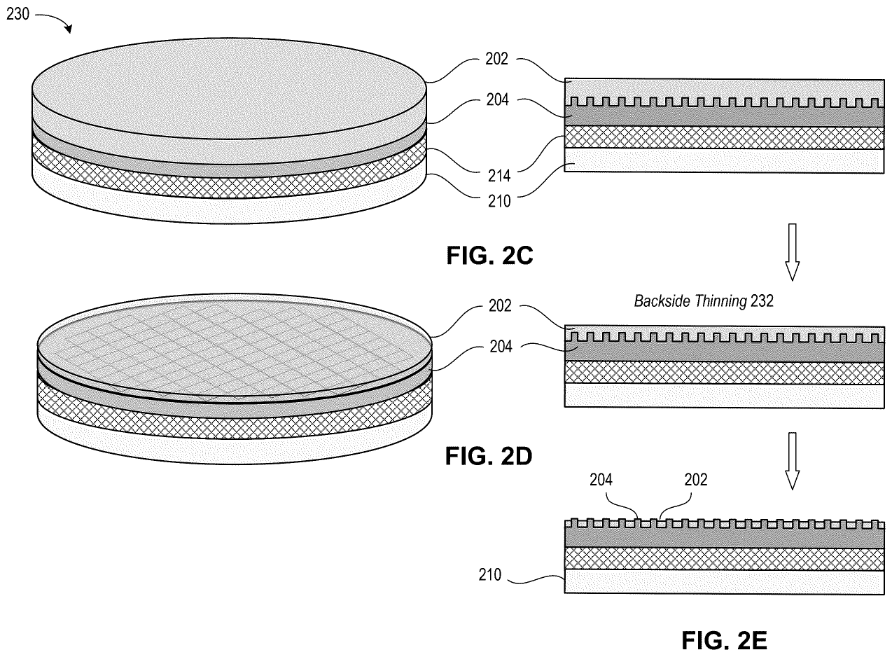

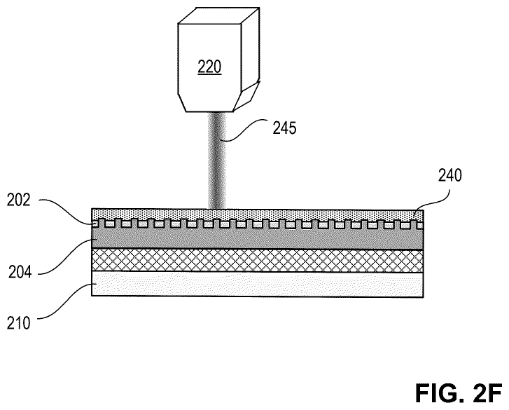

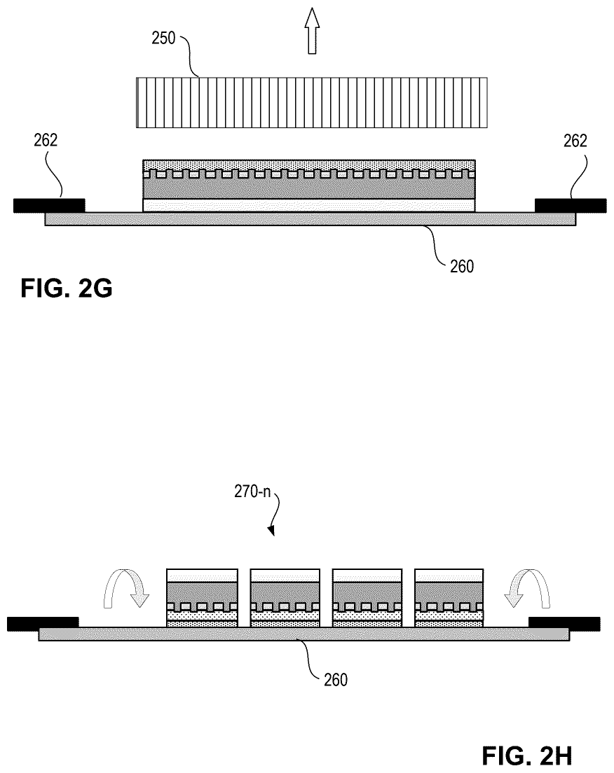

FIG. 1 illustrates schematically stresses in an example substrate structure 100 that can be mitigated using the techniques of the instant disclosure. Example substrate structure 100 includes a substrate 102 and a set of features 104 deposited (or otherwise formed) thereon. The set of features 104 can include any devices (e.g., transistors, memory and/or logic) and/or additional circuitry (e.g., a wire interconnect). The exploded view in FIG. 1 further illustrates an example feature 104-1 of the set of features 104 having a deformation. The deformation (strain) of the example feature 104-1 illustrated in FIG. 1 may not be representative of the geometry of the example feature 104-1 while the example feature 104 remains attached to substrate 102. Such a deformation can be fully revealed after the example feature 104-1 is formed into a die (e.g., using various operations illustrated in FIGS. 2A-2H), including but not limited to deposition of second (third, etc.) set of features (not shown in FIG. 1) and/or one or more films, thinning of the substrate 102, cutting and segmenting the formed stacked structure (that includes substrate 102, the first set of features 104, and/or any additional deposited materials) into individual dies, and/or the like. Prior to transforming substrate structure 100 into individual dies, substrate structure 100 can have a smaller (than illustrated in FIG. 1) deformation but a substantial stress. To prevent this stress from causing a deformation upon cutting the substrate structure 100 into individual dies, the stress can be corrected using one or more techniques disclosed below.

More specifically, existing deformation of substrate 102 (with the first set of features 104 deposited thereon) can be measured (e.g., using optical measurements techniques) and parameters for an optimal SCL can be selected, including SCL's material, thickness, and/or the like. For example, the SCL can be selected to have a tensile or compressive stress. Although different portions of substrate 102 can have tensile stress (σⱼₖ>0), other portions of substrate 102 can have compressive stress (σⱼₖ<0), while yet other portions can have anisotropic (saddle-like) stress (e.g., σₓₓ>0, σ_{yy}<0), type and thickness of the SCL can be selected so that the sign of the stress is the same throughout the wafer/features/SCL stack.

Further stress mitigation includes applying an ion (electron, photon) beam to the SCL to modify (e.g., reduce) stress in the SCL to a desired level. Parameters of an ion (or other particles/waves) implantation map (a distribution of local doses of ion implants) n(x,y) can be computed to reduce the local stress in the substrate structure σⱼₖ(x,y) to a degree that brings the shape of the substrate structure to a flat (or nearly flat) shape. A number of techniques can be used for determining an optimal ion implantation map.

The stress-modulation beam can include matter particles (e.g., ions, electrons), electromagnetic waves (e.g., UV light, visible light, infrared light, etc.), and/or a suitable combination thereof. The stress-modulation beam strikes the SCL and changes the bonding network of the SCL. For example, the stress-modulation beam of low energy may interact with surface atoms of the SCL, e.g., removing some of the surface atoms, effectively implementing etching of surface regions of the SCL. The effectiveness of such etching can be controlled by a choice of ion species/radicals/ambient gasses. In another example, the stress-modulation beam of high energy can deposit ions inside the SCL. Particles and/or photons of the beam can break bonds of the bonding network (or crystal lattice) of the SCL forming vacancies therein, and can further cause annealing due to local heating, UV curing, and/or other effects. Substitution defects and/or vacancies created by the particles of the stress-modulation beam modify (e.g., reduce) stress in the SCL and, through the SCL, in the wafer. The intensity and/or dose (the intensity integrated over time) of the stress-modulation beam can vary with a location within the SCL and can be determined (e.g., simulated, modeled, etc.) in a way that maximally relieves the stress in the SCL (and, further, in the wafer). This causes the combination of the wafer, the deposited features/films, and the SCL to flatten and facilitates precise alignment of features that are patterned on the wafer, etched in one or more stacks of layers, and/or the like, and improves quality of the manufactured devices. The intensity/doses of irradiation can be determined based on the measured deformation of the wafer. Multiple techniques can then be used to determine optimal intensity and/or dose of the stress-modulation beam, such as Monte Carlo simulations, influence function computations, and/or other techniques, as disclosed below.

Stresses σⱼₖ(x,y) that can be mitigated using these techniques include, but are not limited to, stresses that occur in the first substrate globally, as a result of film deposition, global wafer thinning, polishing, cleaning, and/or the like. The mitigated stresses can further include stresses that occur in the wafers because of patterning of the substrates, e.g., deposition of features on the substrates, cutting of the substrate (with the stacked structure placed thereon), and/or the like. The stresses σⱼₖ(x,y), if left unmitigated, would result—upon cutting the stacked structure into individual dies and lifting the dies off a support surface—in a deformation (strain) of one or more of the following types. For example, deformations can include a deformation W₁(x,y) from global film deposition, substrate thinning/polishing/cleaning, and/or the like, a deformation W₂(x,y) from wafer patterning with various features, cutting of the wafer, and/or the like, and a die-specific deformation W₃(x,y) that depends on the specific location of the die on the substrate (e.g., near the center of the substrate, closer to the edge of the substrate, etc.). According to Hooke's law, deformations W₁, W₂, W₃, etc., which occur after die segmentation/lifting, can be proportional to the stresses σⱼₖ(x,y) that existed prior to the segmentation/lifting. To relate deformations W₁, W₂, W₃ to stresses σⱼₖ(x,y), a substrate (e.g., the first substrate) with various features (e.g., the first/second sets of features, SCL, and/or various other films, such as protection films) can be modeled using a plate theory of elastic media. The techniques for determining stresses and deformations can include numerical solution of the elastic plate equations, finite difference methods, influence function (Green's function) techniques, and/or the like. In some embodiments, the second substrate can have low deformation/stress, e.g., by virtue of not hosting patterned structures (and serving as a carrier wafer).

Advantages of the disclosed embodiments include but are not limited to correcting deformations of die-forming wafers to prevent die warping during die-to-die and/or die-to-wafer semiconductor manufacturing for more accurate alignment of die features.

FIGS. 2A-2H illustrate an example semiconductor die manufacturing process, according to at least one embodiment. FIG. 2A shows a perspective view of a sample that includes substrate 202 supporting features 204. In some embodiments, substrate 202 may have previously undergone any additional treatment, such as annealing. Features 204 can include DRAM features, e.g., stacks of transistors and capacitors, interconnect circuitry, uniform (unpatterned) films, patterned films, die boundaries, chip boundaries, area boundaries, slits, channels, and/or any other applicable features. Features 204 can be deposited (or otherwise formed) using atomic layer deposition techniques, photolithography techniques, etching techniques, chemical-mechanical polishing (CMP) techniques, and/or any other techniques.

As illustrated in FIG. 2B, substrate 202 (with features 204) can be rotated with substrate 202 facing up and bonded with a carrier substrate 210. Carrier substrate 210 can be a glass wafer (e.g., SiO₂ wafer), a silicon wafer, a corundum wafer, and/or any other suitable type of wafer. Bonding of substrate 202 to carrier substrate 210 can be facilitated by a suitable adhesion layer 214, e.g., a polyimides layer, a spin-on glass layer, a photoresist, and/or the like. In some embodiments, in lieu of the adhesion layer 214, a fusion bonding may be performed to bond first substrate 202 to carrier substrate 210.

FIG. 2C depicts a bonded product 230 in which substrate 202 and carrier substrate 210 enclose features 204, and adhesion layer 214 (and can further enclose any additional layers, films, patterns, and components). (FIGS. 2C-2E illustrate both the perspective view of the product and its cross-sectional view.)

As illustrated in FIG. 2D and FIG. 2E, substrate 202 can undergo backside thinning 232 until features 204 (or a portion thereof) are exposed through the backside of the substrate 202 (FIG. 2E). Backside thinning 232 can include grinding, CMP, wet etching, dry etching, polishing, and/or other techniques or a combination thereof. In some embodiments, exposing features 204 can include forming Through-Silicon VIAs or TSVs (vertical electrical connections through features 204 and/or the substrate 202).

As illustrated in FIG. 2F, a stress-compensation layer (SCL) 240 can be deposited (or otherwise formed) on the product. The SCL 240 can include a polymer film, a carbon layer, an oxide layer, and/or some other layer. SCL 240 can cover features 204. SCL 240 can be deposited using chemical vapor deposition (CVD) techniques, in some embodiments. In some embodiments, SCL 240 can be made from silicon nitride Si₃N₄ or some other material whose stress can be efficiently controlled during deposition of SCL 240. The level of stress in SCL 240 can be set at SCL 240 deposition by controlling conditions in the processing chamber during deposition of SCL 240, including but not limited to concentration of argon and/or nitrogen atoms (ions) in the environment of the processing chamber, voltage, temperature, and/or the like. In some instances, SCL 240 can have a tensile stress while, in other instances, SCL 240 can have a compressive stress. The type of SCL (tensile vs. compressive) can be determined by a (measured and/or inferred) sign of stress in substrate 202 prior to the SCL deposition. Similarly, the magnitude of stress of SCL 240 can be determined (measured and/or inferred) based on a magnitude of stress in substrate 202.

As further illustrated in FIG. 2F, a stress-modulation beam 245 can be applied to SCL 240 to deliver a position-dependent dose of particles (e.g., ions or electrons) and/or photons n(x,y), where x,y are in-plane coordinates within the wafer/SCL plane. Stress-modulation beam 245 can be generated by a suitable collimating and focusing column 220. Application of stress-modulation beam 245 causes stress in the sample that contains substrate 202, features 204, second feature 240, and SCL 240 to decrease, resulting in the flattening of the sample (reduced deformation).

In some embodiments, a material of SCL 240, a thickness of SCL 240, a target stress of the SCL 240, and/or settings of stress-modulation beam 245 can be determined in view of an estimated (e.g., predicted) deformation caused by various processing operations (e.g., deposition, etching, cutting, and/or the like) being performed to manufacture one or more devices (e.g., semiconductor devices). Estimated (in contrast to presently measured) deformation can take into account one or more operations that are yet to be performed, e.g., to proactively anticipate and mitigate deformation that occurs after the SCL 240 is formed and the stress-modulation beam 245 is applied thereto.

As illustrated in FIG. 2G, a suitable effector 250, e.g., electrostatic chuck, a suction effector, and/or the like, can engage the SCL 240. In some embodiments, an additional protection layer (not shown in FIG. 2G) can be formed on SCL 240 to protect SCL 240 from mechanical contact with the effector 250. The effector 250 can mechanically separate (debond) the carrier substrate 210 from the remaining portion of the structure, e.g., from (the remainder of) first substrate 202, features 204, SCL 240, and/or other components, as can be applicable. The effector 250 can transport the product to a suitable receiving surface 260, which can be an adhesive tape, another substrate, or some other surface capable of securely holding the structure. The receiving surface 260 can be secured in place by a support structure 262, e.g., a support ring attached to the adhesive tape.

After placing the sample on the receiving surface 260, the effector 250 can disengage from the sample that can be cut into individual dies 270-n, as illustrated in FIG. 2H. The dies 270-n can be lifted from the receiving surface 260 by a suitable die-sized effector, moved, stacked, rotated (front side up again, as shown in FIG. 2H) and/or processed in some other suitable way. In one non-limiting example, individual dies 270-n can have a 10 mm×10 mm×15 μm size (or any other suitable size) with multiple, e.g., 10-12 dies stack on top of each other to form a memory (e.g., Dynamic Random-Access Memory or DRAM) unit.

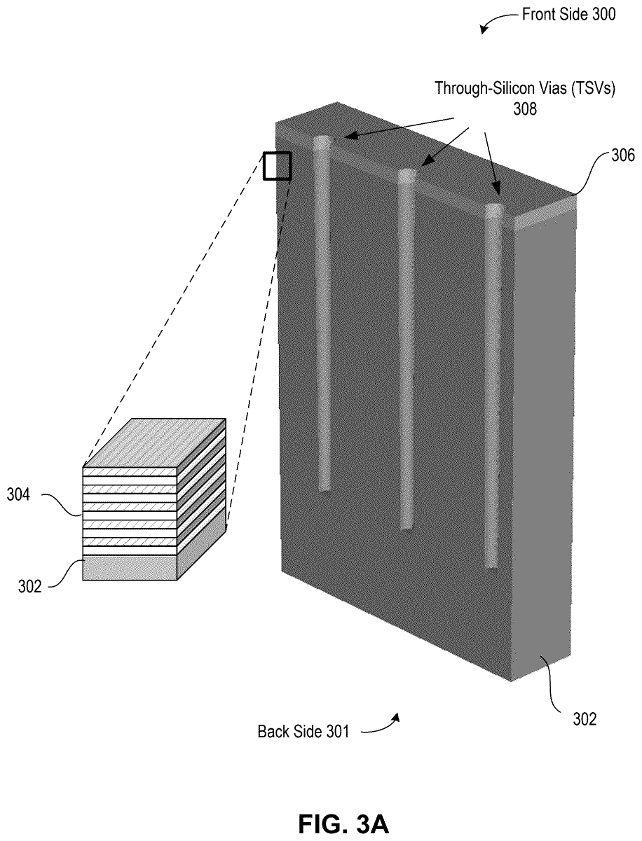

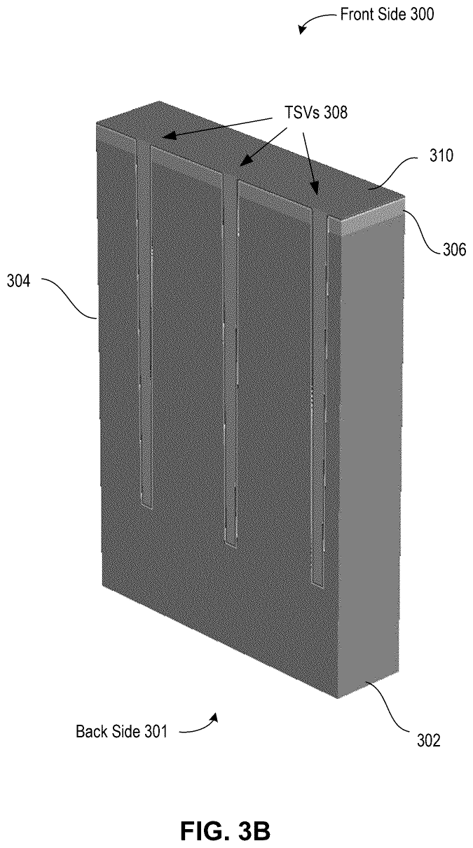

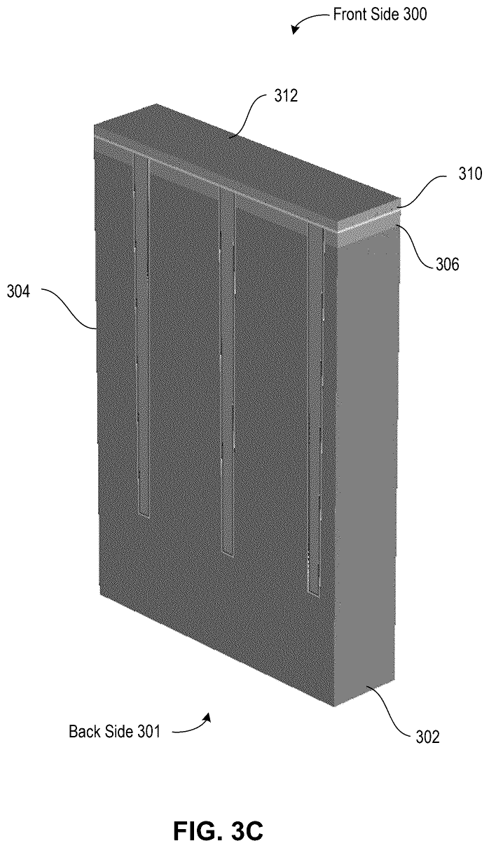

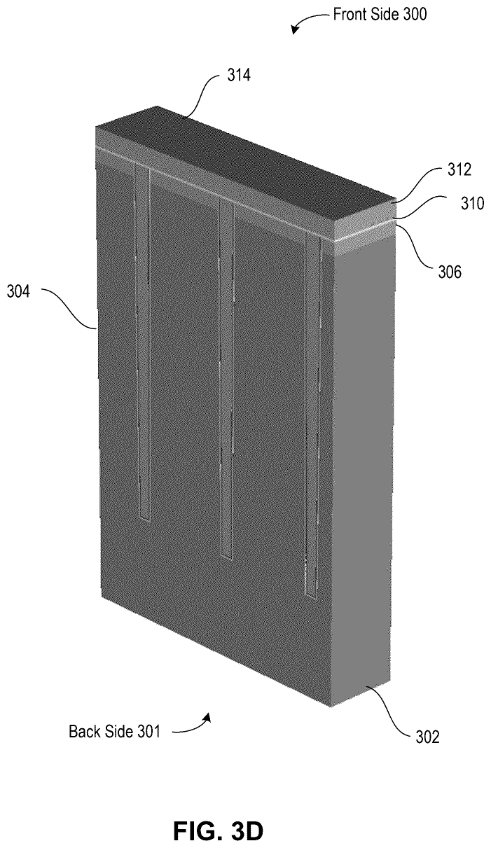

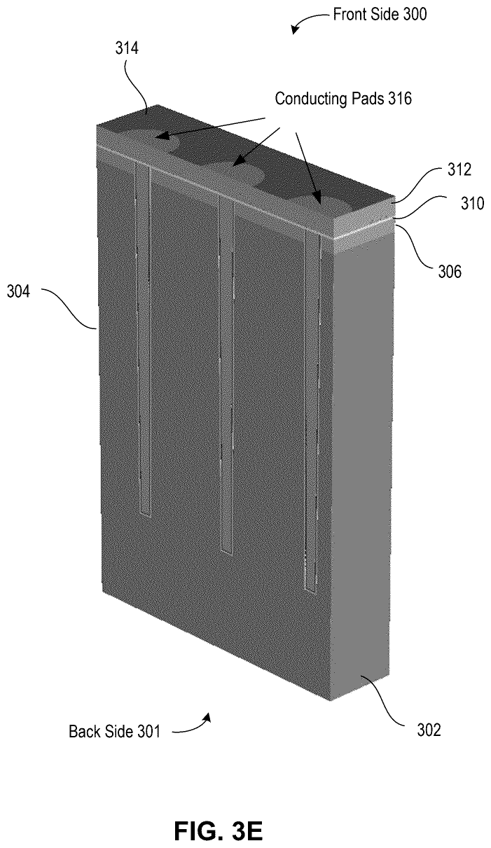

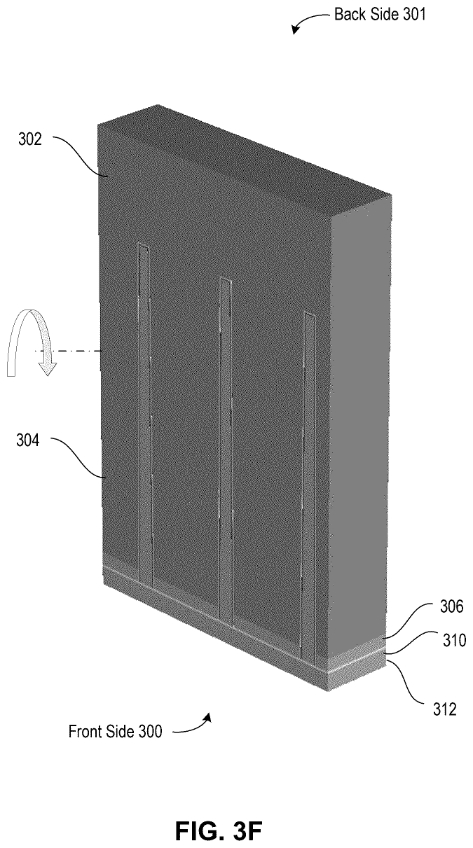

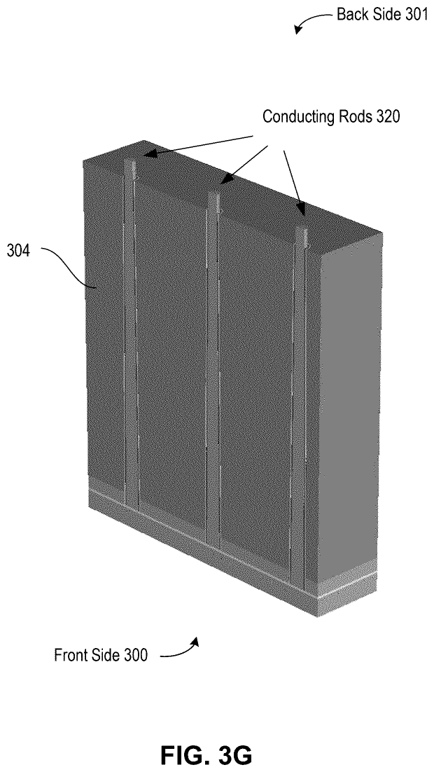

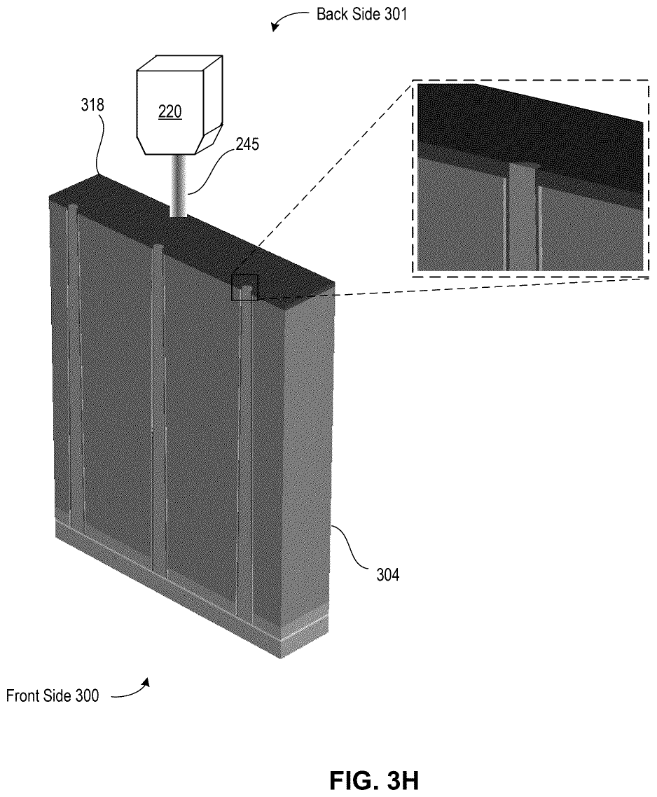

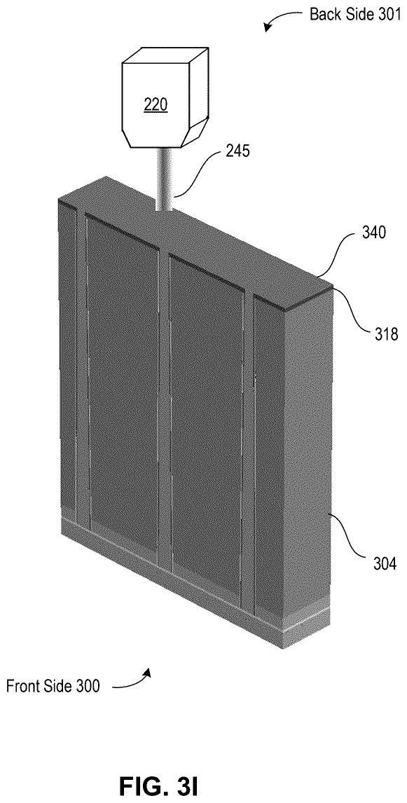

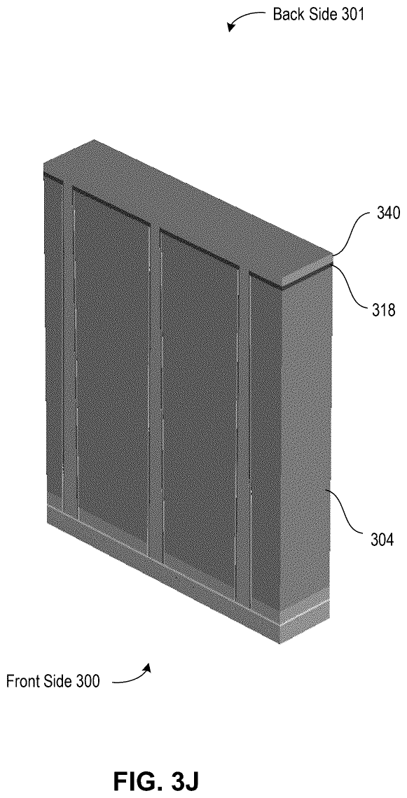

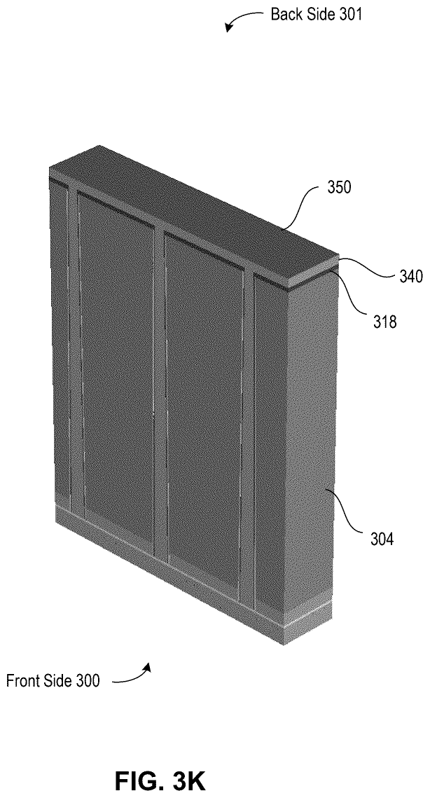

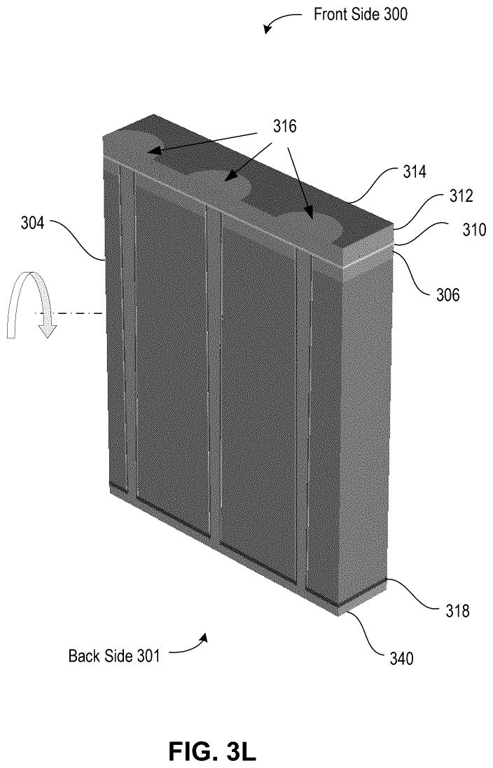

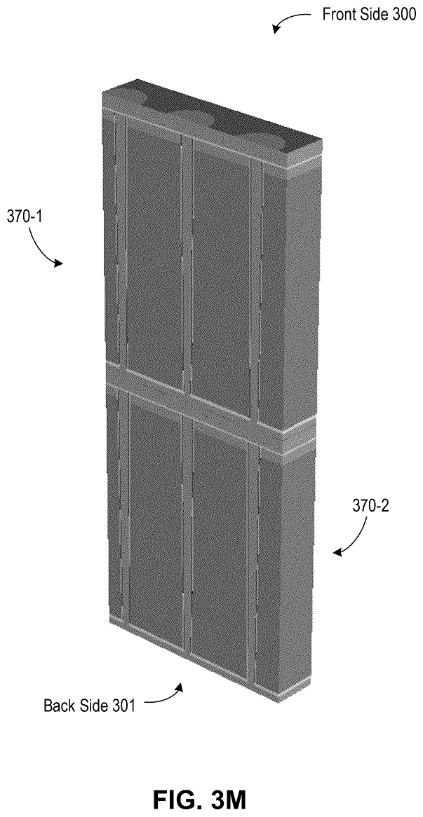

FIGS. 3A-3M illustrate a process of die semiconductor manufacturing that deploys stress-compensation layers and stress-modification beams for local die wrap correction, according to at least one embodiment. Although FIGS. 3A-3M illustrate processing of DRAM devices, it should be understood that manufacturing of numerous other structures, features, and devices can be performed using the same or similar techniques. FIG. 3A illustrates a vertical structure (referred to as “product” herein) having a front side 300 (device side) and a back side 301 (wafer side). A substrate 302 (e.g., a silicon wafer) of any suitable size, e.g., 30 cm, supports a stack 304 of layers/films grown (or deposited) on substrate 302. Stack 304 can be a stack of DRAM features, e.g., DRAM memory cells. DRAM memory cells may be arranged in a two-dimensional (2D) layer of DRAM memory cells. In some embodiments, DRAM memory cells may be arranged in three-dimensional (3D) stack of layers of DRAM memory cells, e.g., as illustrated schematically with the magnified portion of FIG. 3A. The callout portion of FIG. 3A illustrates the top portion of substrate 302 with several DRAM layers.

The stack 304 can be covered with a cap layer 306, which can be made of an oxide material (e.g., silicon oxide). In some embodiments, cap layer 306 (and/or other protection layers used in conjunction with the disclosed techniques) can be made of silicon nitride (Si₃N₄). In some embodiments, the thickness of cap layer 306 can be between 500-2000 nm but can be less than 500 nm or more than 2000 nm, in other embodiments. A set of Through-Silicon VIAs (TSVs) 308 can be etched through a target depth of stack 304. For example, a mask (not shown in FIG. 3A) can be deposited on top of stack 304 and a photoresist layer (now shown in FIG. 3A) can be deposited on top of the mask. A photolithography can then be used to create a target pattern in the photoresist layer, e.g., a pattern of channel holes to be transferred to the mask and then further to stack 304. More specifically, an etch process, e.g., Mask Open Etch, can be used to transfer the target pattern to the mask. The Mask Open etch creates a pattern of TSVs 308 (as well as any other features, including but not limited to slits, and/or any other openings) in the mask. An additional etch process—a channel hole etch, memory hole etch, dielectric etch—is then used to transfer the pattern of TSVs (and/or other features) to stack 304 to form TSVs 308 that can extend towards substrate 302, in some embodiments. (The etch process can consume the mask; unconsumed parts of the mask can be removed, e.g., dissolved or evaporated.) Although, for simplicity, FIG. 3A illustrates cylindrical TSVs 308, TSVs of other cross-sections, e.g., slits, etc., can be etched in a similar manner.

As illustrated in FIG. 3B, TSVs 308 can be filled with a suitable conducting layer 310, e.g., made of copper or some other conducting material, to form conducting wires that provide electrical access to the deposited stack 304. As illustrated in FIG. 3C, another cap layer 312 (e.g., SiO₂ layer) can be formed to protect the conducting material. Additionally, as illustrated in FIG. 3D, a hybrid bonding mold layer 314 can be formed on top of the cap layer 312 to facilitate efficient copper-to-copper bonding and, correspondingly, reliable die stacking. Hybrid bonding mold layer 314 can include a silicon carbonitride (SiCN) layer, and/or the like. As illustrated in FIG. 3E, conducting pads 316 can be formed in cap layers 306 and 312 to ensure electrical contact with the TSVs.

As illustrated in FIG. 3F, the product can be flipped, e.g., by removing the product from a processing chamber, rotating the product, and reinserting the product back into the processing chamber. These steps can be performed by flipping the wafer in the Factory Interface (FI) of the mainframe of the process tool. Although not shown (for the ease of viewing) in FIG. 3F, the front side 300 of the product can be adhered to a second, e.g., carrier substrate 210 (with reference to FIG. 2B).

As illustrated in FIG. 3G, the back side 301 of the product can undergo thinning to expose ends of conducting rods 320. In one example embodiment, the thinning may first include grinding (or polishing) to the depth of the ends of conducting rods 320 followed by chemical etching (e.g., wet etching, dry etching, etc.) to recess the surface and expose a target length of the rods.

As illustrated in FIG. 3H, a stress-compensation layer (SCL) 318 can be deposited (e.g., using CVD or other techniques) on the back side 301 of the product. In some embodiments, SCL 318 can be made of silicon nitride (Si₃N₄). In other embodiments, SCL 318 can be made from a different material. In some embodiments, SCL 318 can be made from a material that is the same as the material of cap layers 306 and/or 312 (with reference to, e.g., FIG. 3E). In some embodiments, cap layers 306 and/or 312 can be low-stress layers while SCL 318 can have a higher stress. The level of stress in SCL 318 can be set by controlling conditions in the processing chamber during deposition of SCL 318, including but not limited to concentration of argon and/or nitrogen atoms in the environment of the processing chamber, voltage, temperature, and/or the like. In some instances, SCL 318 can have tensile stress while, in other instances, SCL 318 can have compressive stress. The type of SCL (tensile or compressive) can be determined by a (measured and/or inferred) sign of stress in the product prior to the SCL deposition. Similarly, the magnitude of stress of SCL can be determined (measured and/or inferred) based on a magnitude of stress in the product.

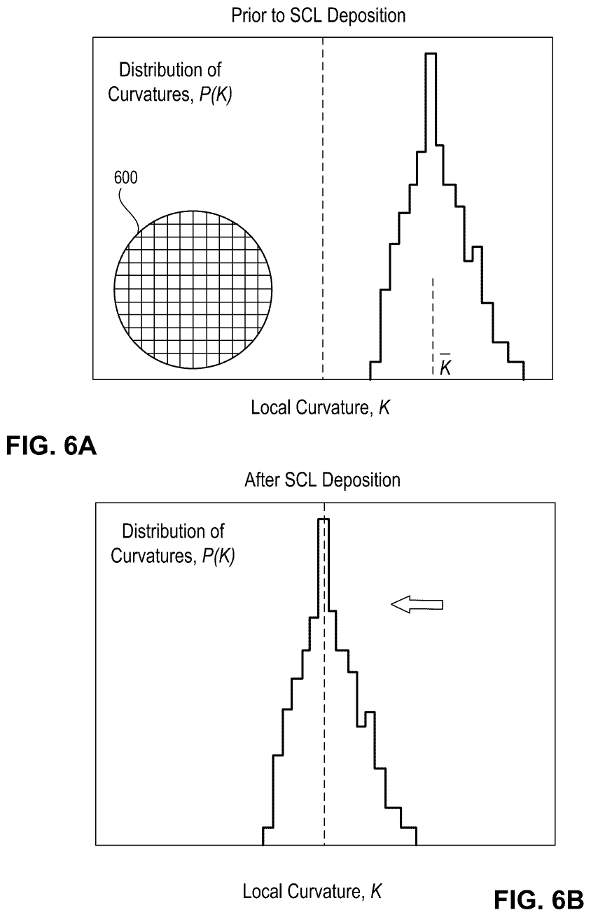

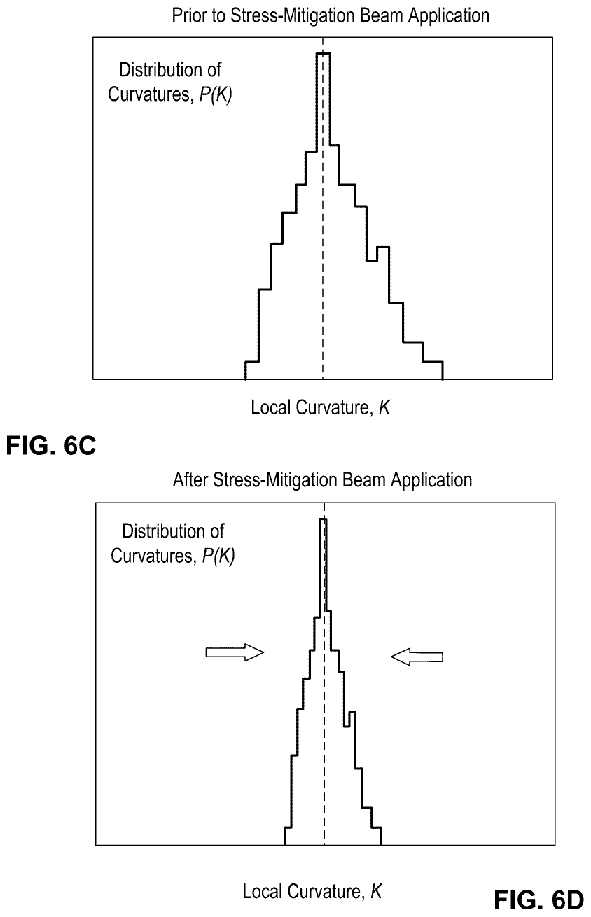

As disclosed in conjunction with FIGS. 6A-6B below, thickness and properties (e.g., the amount of stress) of SCL 318 can be selected to ensure that the distribution of local curvatures in the product has a zero (or close to zero) mean (or median), to reduce deformation of the dies to be obtained upon eventual cutting of the product into dies (e.g., as depicted in FIG. 2H). In some embodiments, to reduce the leakage current (and, correspondingly, energy consumption) in the memory devices made from the dies, SCL 318 can be formed at temperatures not exceeding 180 degrees Celsius, e.g., at about 150 degrees.

As further illustrated in FIG. 3H, a stress-modulation beam 245 can be applied to SCL 318 to deliver a position-dependent dose of particles and/or photons n(x,y), where x,y are in-plane coordinates within the SCL plane. Stress-modulation beam 245 can be generated by a suitable collimating and focusing column 220. Application of stress-modulation beam 245 causes stress in the product that contains stack 304, and SCL 318 to decrease, resulting in the flattening of the product (reduced deformation). As disclosed in conjunction with FIGS. 6A-6B below, the local doses of stress-modulation beam 245 delivered to various locations of the product can be computed to narrow the distribution of local curvatures P(K) of the product.

In some embodiments, the surface of SCL 318 can undergo polishing (e.g., CMP) to re-expose the ends of the conducting rods. In some embodiments, prior to polishing the SCL 318 can be covered with a sacrificial cap layer (e.g., a silicon oxide layer) that is removed in the course of polishing but whose presence facilitates formation of a smoother surface of the SCL 318.

As illustrated in FIG. 3I, a cap layer 340 can be formed on the SCL 318. In some embodiments, stress-modulation beam 245 can be applied to cap layer 340, e.g., substantially as applied to SCL 318 and described above in conjunction with FIG. 3H. In some embodiments, stress-modulation beam 245 can be applied to SCL 318 but not cap layer 340. In some embodiments, stress-modulation beam 245 can be applied to cap layer 340 but not SCL 318. In some embodiments, stress-modulation beam 245 can be applied both to SCL 318 and cap layer 340.

In some embodiments, stress-modulation beam 245 can be applied to cap layer 340 after some portion of cap layer 340 has been formed on SCL 318 but before a remaining portion of cap layer 340 is added. For example, as illustrated in FIG. 3J, after the stress-modulation beam is no longer applied to the cap layer 340, the thickness of the cap layer 340 has been further increased.

As illustrated in FIG. 3K, a hybrid bonding (or bump bonding) mold layer 350 (e.g., a silicon carbonitride layer, etc.) can be formed on top of the cap layer 340 to facilitate robust and reliable inter-die bonding at the back side 301. As illustrated in FIG. 3L, the product can then be rotated to bring the front side 300 up again. The product can be cut into dies, e.g., as illustrated in FIG. 2H. As illustrated in FIG. 3M, multiple dies, e.g., dies 370-1 and 370-2, can be stacked on top of each other being electrically connected with conducting pads, conducting TSVs, and/or other suitable interconnect circuitry.

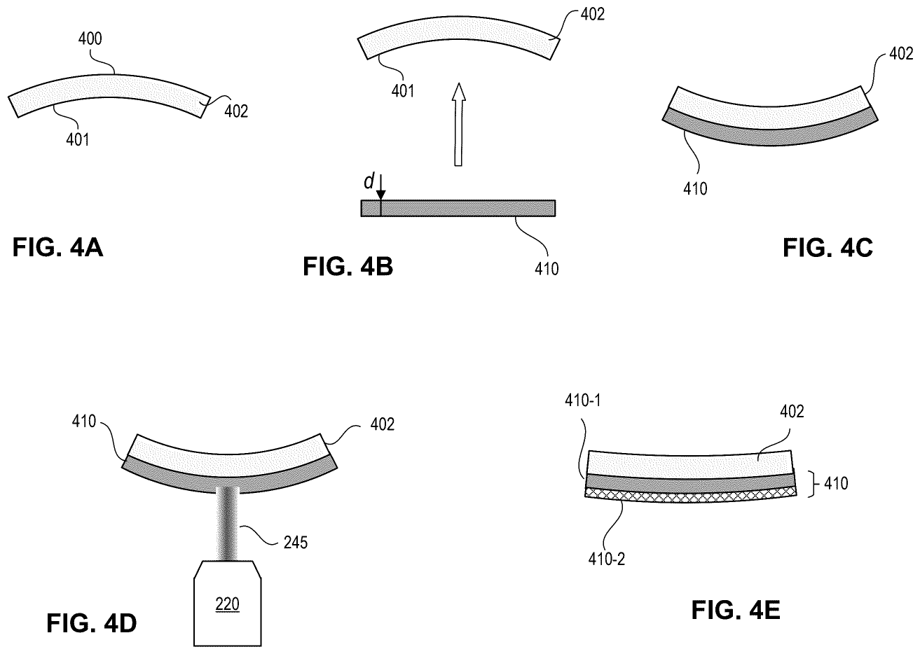

FIGS. 4A-4E illustrate schematically a process of correcting a product deformation using a stress-modulation beam applied to the product, according to at least one embodiment. The process of FIGS. 4A-4E can be used with operations illustrated in FIG. 2F, FIG. 3H and/or FIG. 3I.

FIG. 4A depicts a substrate 402 having a deformation, which can include a paraboloid bow deformation (with negative coefficient A₄<0, as illustrated) and can further include other deformations, including saddle deformation, residual deformation, etc. The wafer's front side 400 can include any number of features, e.g., deposition and/or etching patterns, a stack of layers/films, and/or any other structures. FIG. 4B illustrates deposition of an SCL 410 on the back side 401 of substrate 402. SCL 410 can be (or include) a silicon nitride layer or some other type of material. In some embodiments, SCL 410 can include layers of multiple materials. In some embodiments, a material of SCL 410 can be selected in view of the sign of coefficient A₄. For example, for a negative bow, A₄<0, SCL 410 can be selected to have a compressive stress (as illustrated in FIGS. 4B-4E), such that SCL 410, after deposition, stretches out and corrects the negative bow. Conversely, for a positive bow, A₄>0, SCL 410 can be selected to have a tensile stress (such that SCL 410 contracts after deposition). SCL 410 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, thickness d of SCL 410 can be selected to overcorrect the wafer deformation to some degree, e.g., as illustrated in FIG. 4C where a positive paraboloid is overcorrected to a negative paraboloid bow. The thickness-dependent paraboloid bow correction A_{corr}(d) changes wafer deformation from s(r,φ) to s_{corr}(r,φ):

$${s}_{c o r r} ( r , ϕ ) = s ( r , ϕ ) + {A}_{c o r r} ( d ) \cdot {Z}_{4} ( r , ϕ ) .$$

The degree of overcorrection can be chosen in conjunction with a type and parameters (e.g., energy, dose, etc.) of a specific stress-modulation beam 245 to be used on SCL 410. The overcorrection can make the combined structure of substrate 402 and SCL 410 susceptible to further control of stress (and thus control of deformation of the wafer h_{corr}(r,φ)). As illustrated in FIG. 4D, collimating and focusing column 220 can generate a stress-modulation beam 245 that strikes SCL 410 and changes its elastic properties, e.g., by creating vacancies, breaking crystal bonds, depositing ions, and/or via any other applicable mechanisms. Stress-modulation beam 245 can carry photons, electrons, silicon ions, phosphorus ions, argon ions, neon ions, xenon ions, krypton ions, and/or the like. In some embodiments, the energy and type of ions in stress-modulation beam 245 can be selected to limit the implanted ions to the volume of SCL 410 without allowing the ions to reach substrate 402 (and/or any layers/films deposited on substrate 402). Ions that lodge in SCL 410 create substitution defects therein. Additionally, the ions leave a trail of vacancy defects along paths of propagation in SCL 410. The substitution defects and/or vacancies mitigate (e.g., reduce) stress in SCL 410 and can reduce the degree of stress overcorrection caused by the SCL deposition. This causes the combination of substrate 402 and SCL 410 to flatten. In some embodiments, the stress-modulation beam can increase the degree of stress (e.g., in the instance of a curing UV beam, in one example).

In some embodiments, the number of particles (or photons) ΔNᵢ deposited per small area ΔA=ΔxΔy (or the total amount of photon energy applied to this area) of substrate 402 can be determined using simulations (performed as described in more detail below) based on the local value of the corrected deformation s_{corr} (r,φ), which may include a saddle deformation, a residual deformation, and the part of the paraboloid bow deformation A_{corr}(d)+A₄ that has been overcorrected by the deposition of SCL 410. The target local density n(x,y)=ΔNᵢ/ΔxΔy of the particles can be delivered by controlling the scanning velocity v of stress-modulation beam 245. In some embodiments, stress-modulation beam 245 has a profile that can be approximated with a Gaussian function, e.g., the particle flux j(ρ)=j₀ exp(−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that includes the following number of ions:

$$\frac{Δ {N}_{i}}{Δ x Δ y} = \frac{{j}_{0}}{v} {\int }_{- ∞}^{∞} d x {e}^{- {x}^{2} / {a}^{2} - {y}^{2} / {b}^{2}} = \frac{{j}_{0} \sqrt{π}}{v a} {e}^{- {y}^{2} / {b}^{2}} .$$

Correspondingly, by reducing the scanning velocity v, the number of particles received by various regions of SCL 410 can be increased, and vice versa. Additionally, stress-modulation beam 245 can perform multiple scans with different offsets y so that various points of SCL 410 receive multiple doses of particles with different factors e^{-y}^{²}^{/b}^{²} that can average to a target dose. For example, after n passes of stress-modulation beam 245, each made with a respective velocity vₖ at a different distance yₖ from the center of the beam to the area ΔxΔy, the total dose of particles (or amount of electromagnetic radiation) received by this area will be

$${n ( x , y ) = \frac{Δ {N}_{i}}{Δ x Δ y} \vert}_{total} = {j}_{0} \sqrt{π} {\sum }_{k = 1}^{n} \frac{{e}^{- {y}_{k}^{2} / {b}^{2}}}{a {v}_{k}} .$$

As illustrated in FIG. 4E, the presence of a stress-mitigated portion 410-2 of SCL 410 results in a significant mitigation of deformation of substrate 402, including saddle and residual deformations (the remaining portion 410-1 of SCL 410 may be unmitigated or weakly mitigated and may include deeper regions o SCL 410 with little exposure to stress-modulation beam 245).

In some embodiments, the intensity and/or total amount of irradiation per various areas of substrate 402 can be determined using simulations, e.g., Monte Carlo simulations. The Monte Carlo simulations can be performed for a film made of the actual material used in SCL deposition and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to SCL 410 (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of masks/layers, angles of particle incidence on the films, and/or the like.

In some embodiments, the implantation map n(\vec{r}) can be computed using an influence function G (\vec{r};\vec{r}′) that characterizes a response (e.g., deformation) at a point \vec{r} of the wafer as caused by a point-like force applied at another point \vec{r}′ of substrate 402. In some embodiments, the influence function G(\vec{r};\vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, substrate deformation s(\vec{r})=s_{quad}(\vec{r})+sᵣₑₛ(\vec{r}) can be represented (decomposed) as a combination of a quadratic s_{quad}(\vec{r}) and residual (non-quadratic) sᵣₑₛ(\vec{r}) contributions. The quadratic deformation can include a parabolic (paraboloid) part, which has the complete axial symmetry, and a saddle part. The thickness d of SCL 410 can be computed (or empirically determined) in such a way that the mask is to apply a desired target stress to substrate 402. To eliminate a non-uniform saddle deformation, SCL 410 can be of such thickness/material that turns the saddle deformation into a cylindrical deformation having a definite sign throughout the area of substrate 402. The uniform-sign cylindrical deformation (as well as a residual higher-order non-quadratic deformation) can then be mitigated with irradiation by stress-modulation beam 245. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of SCL 410 (e.g., type and thickness) while the remaining cylindrical deformation (and the higher-order residual deformation) can be addressed by appropriately selected ion or photon irradiation doses n(\vec{r}).

In some embodiments, mitigation of a cylindrical deformation or a saddle deformation can include identifying principal axes (directions) of the cylinder/saddle and a magnitude of the cylindric/saddle deformation and directing stress-modulation beam 245 into appropriately selected edge regions of SCL 410. For example, individual edge regions to which the stress-modulation beam 245 is directed can have a width that is at or below 30% of a diameter of substrate 402. Residual higher-order (ripple) deformations can then be mitigated with further irradiation into the area of SCL 410.

Some of these techniques will now be described in more detail. In one embodiment, a vertical profile of wafer (or any other product) deformation z=h(\vec{r}) can be measured using optical metrology techniques. For example, an interferogram of the profile h(\vec{r}) can be obtained using optical interferometry measurements. The wafer profile h(\vec{r}) can then be represented via a number of parameters that qualitatively and quantitatively characterize geometry of the wafer deformation. In some embodiments, a set of Zernike (or a similar set of) polynomials can be used to represent the wafer profile,

$$h ( \vec{r} ) = {\sum }_{j} {A}_{j} {Z}_{j} ( \vec{r} ) ,$$

where the planar radius-vector \vec{r}=(r,φ) may be represented as the radial coordinate r and the polar angle φ within the (average) plane of the wafer. Consecutive coefficients A₁, A₂, A₃, A₄ . . . represent weights of specific geometric features (elemental deformations) of substrate 402 described by the corresponding Zernike polynomials Z₁(r,φ), Z₂(r,φ), Z₃(r,φ), Z₄(r,φ) . . . . (Herein, the Noll indexing scheme for the Zernike polynomials is being referenced.) The first three coefficients are of less interest as they describe a uniform shift of substrate 402 (coefficient A₁, associated with the Z₁(r,φ)=1 polynomial), a deformation-free x-tilt that amounts to a rotation around the y-axis (coefficient A₂, associated with the Z₂(r,φ)=2r cos φ polynomial), and a deformation-free x-tilt that amounts to a rotation around the x-axis (coefficient A₃, associated with the Z₃(r,φ)=2r sin φ polynomial) that can be eliminated by a realignment of the coordinate axes. The fourth coefficient A₄ is associated with Z₄(r,φ)=\sqrt{3}(2r²−1) and characterizes an isotropic paraboloid deformation (“bow”). The fifth A₅ and the sixth A₆ coefficients are associated with Z₅(r,φ)=\sqrt{6}r² sin 2φ and Z₆ (r,φ)=\sqrt{6}r² cos 2φ polynomials, respectively, and characterize a saddle-type deformation. The A₅ coefficient characterizes a saddle shape that curves down (A₅>0) or up (A₅<0) along the diagonal y=x and curves up (A₅>0) or down (A₅<0) along the diagonal y=−x. The A₆ coefficient characterizes a saddle shape that curves down (A₆>0) or up (A₆<0) along the x-axis and curves up (A₆>0) or down (A₆<0) along the y-axis. The higher coefficients A₇, A₈, etc., characterize progressively faster variations of the wafer deformation h(r,φ) along the radial direction, along the azimuthal direction, or both and collectively represent a residual deformation,

$${h}_{r e s} ( r , ϕ ) = h ( r , ϕ ) - {\sum }_{j = 4}^{6} {A}_{j} {Z}_{j} ( r , ϕ ) .$$

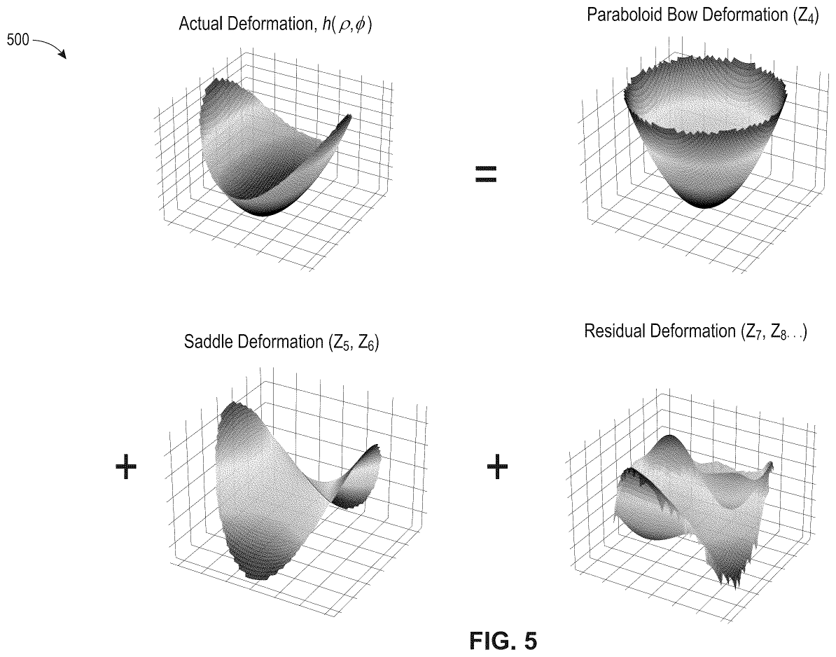

FIG. 5 illustrates an example Zernike polynomial decomposition 500 of one actual deformation h(r,φ) (top left) of a wafer (e.g., substrate 402), in arbitrary units, into a paraboloid bow deformation A₄Z₄(r,φ) (top right), a saddle deformation A₅Z₅ (r,φ)+A₆Z₆(r,φ) (bottom left), and a residual deformation, hᵣₑₛ(r,φ) (bottom right), according to at least one embodiment.

FIGS. 6A-6D are schematic illustrations of a die-level control of warp as part of semiconductor manufacturing, in accordance with at least one embodiment. In some embodiments, optical inspection measurements can determine a profile of a substrate, z=h(x,y), e.g., as disclosed in conjunction with FIGS. 4A-4E. The profile h(x,y) can be determined at any stage of a device manufacturing process. For example, with reference to the example process disclosed in conjunction with FIGS. 3A-3M, the profile can be determined prior to deposition of SCL 318 (with reference to FIG. 3H) and/or prior to deposition of cap layer 340 (with reference to FIG. 3I). The profile h(x,y) can be used to determine a local curvature of a product, e.g., its Gaussian curvature,

$$K ( x , y ) = \frac{{\partial }_{x}^{2} h \cdot {\partial }_{y}^{2} h - {( {\partial }_{x} {\partial }_{y} h )}^{2}}{{[ 1 + {( {\partial }_{x} h )}^{2} + {( {\partial }_{y} h )}^{2} ]}^{2}} .$$

In some embodiments, the substrate can be represented via a grid 600 of cells having a size that corresponds to the size of the dies, e.g., 10 mm×10 mm, or some other suitable size. The Gaussian curvature K(x,y) can be used to obtain representative curvature values Kᵢⱼ for various cells ij (where i stands for the horizontal cell index and j stands for the vertical cell index). In some embodiments, the representative curvature values Kᵢⱼ can correspond to the curvature at the center of the respective cell, the curvature averaged over the area of the respective cell, the curvature weight-averaged for respective cell (with some weight function that depends on the distance to the center of the cell), and/or some other suitable representative measure of the cell's curvature.

The computed curvature values Kᵢⱼ can be represented via a distribution of curvatures, P(K), e.g., a number (count) of cells with a particular curvature value K. An illustrative distribution P(K) is shown in FIG. 6A (in some arbitrary units). As illustrated in FIG. 6A, the mean (or median) of the distribution P(K) may be centered at a non-zero value K̅. The parameters, e.g., thickness and/or stress level, of the SCL can then be determined to facilitate the shift of the mean (or median) of the distribution P(K) from K̅ to K≈0, after deposition of the SCL, as illustrated in FIG. 6B.

Even though the deposition of the SCL centers the distribution P(K) around a zero (or near-zero) local curvature, the SCL imparting a uniform parabolic bow to the substrate may not change significantly the width of this distribution. The narrowing of the distribution can then be achieved by suitably chosen local doses n(x,y) of the stress-modulation beam that is to be applied to various locations x,y of the substrate. For example, a distribution P(K) of curvature values shown in FIG. 6C can be modified to a distribution that is characterized by a substantially smaller width, as illustrated in FIG. 6D. The local doses of radiation can be determined using a variety of techniques, including solving elastic equations describing deformation of the substrate, e.g., a thin-plate equation (Kirchhoff-Love equation), using various suitable techniques, including but not limited to the finite element analysis (FEA) techniques, Green's function calculations, and/or the like. For example, the substrate with various features deposited thereon can be described by a flexural rigidity, D=Et³/12(1−v²), where E is the Young modulus, v is the Poisson ratio, and t is the thickness of the substrate. In some embodiments, the simulations can account for low levels of stress contributed by the vertical copper TSVs (or rods of other conducting materials) that pass through the thickness of the features deposited on substrates.

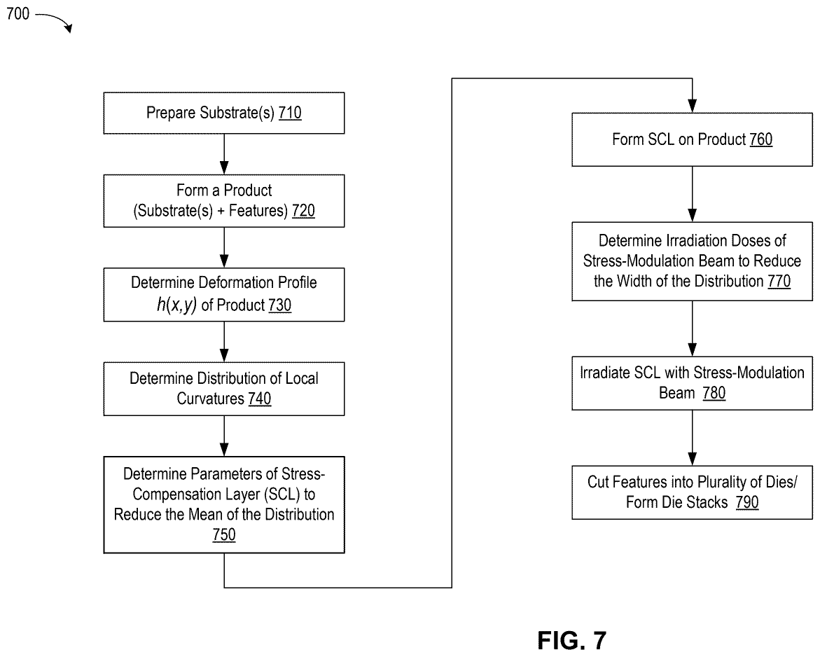

FIG. 7 is a flowchart illustrating an example method 700 of deploying stress-compensation layers and stress-modification beams for local die wrap correction, in accordance with at least one embodiment. Method 700 can be performed to manufacture one or more semiconductor devices using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle wafers, e.g., moving wafers into and out of processing chambers. The transfer chamber can further be connected to a load-lock chamber (Front-End Interface) that can be coupled to one or more Front Opening Unified Pod carriers that hold bare wafers, processed wafers, partially processed wafers, and/or the like. Operations performed by the semiconductor manufacturing system, including any, some or all operations of method 700, can be performed responsive to instructions issued by a suitable computing device having a processing logic and memory to store the instructions.

At block 710, method 700 can include preparing one or more substrates (e.g., substrate 202 in FIG. 2A and carrier substrate 210 in FIG. 2B), including but not limited to obtaining bare substrate(s), preprocessing the bare substrate(s), e.g., polishing the substrate(s), removing stains and/or residue from the substrate(s), and/or performing any number of similar operations. At block 720, method 700 can continue with forming a product that includes a plurality of features (e.g., stack 304 in FIG. 3A) supported by the substrate(s). The features can include any number of patterns, layers, films, slits, masks, holes, and/or the like. For example, the features can include a plurality of DRAM layers and interconnect circuitry, each formed across at least some of the plurality of DRAM layers. In some embodiments, the features can include DRAM features, oxygen layers, nitrogen layers, silicon layers, germanium layers, silicon-germanium alloy layers, and/or any other suitable layers. Various layers can be used as hosts of memory cells, transistors, separations between memory cells/transistors, and/or the like.

In some embodiments, forming the product includes forming the plurality of features on a first substrate and causing a second substrate to adhere to the plurality of features (e.g., as illustrated in FIG. 2B). Forming the product can further include thinning the first substrate to expose at least a subset of features of the plurality of features (e.g., as illustrated in FIGS. 2D-2E). In some embodiments, thinning the first substrate can include grinding the first substrate, dry etching the first substrate, wet etching the first substrate, applying chemical-mechanical polishing to the first substrate, and/or using other similar techniques or a combination thereof.

At block 730, method 700 includes determining a deformation profile of the product. In some embodiments, determining the deformation profile can include obtaining optical inspection data characterizing a profile of the deformation of the product, e.g., measuring the shape of the product, such as a displacement of a surface (e.g., the top surface) of the product as a function of some in-plane coordinates, e.g., polar coordinates z=h(r,φ), Cartesian coordinates, z=h(x,y), or any other suitable coordinates. In some embodiments, operations of block 730 can include decomposition of the determined shape or the deformation profile over a suitable set of polynomials, e.g., Zernike polynomials, and obtaining a set of polynomial expansion coefficients, {Aⱼ}=(A₁,A₂,A₃),A₄,A₅,A₆,A₇, . . . , each coefficient in the set characterizing a degree of presence of a particular elemental geometric shape in the wafer's deformation.

At block 740, method 700 can include determining, using the deformation profile, a distribution of local curvatures of the product. In some embodiments, the distribution of local curvatures of the product includes a plurality of curvature values (e.g., values Kᵢⱼ, as disclosed in conjunction with FIG. 4A), each curvature value of the plurality of curvature values characterizing a degree of curvature of a respective die-size portion of the product.

At block 750, method 700 can include determining one or more properties of a stress-compensation layer (SCL) that reduces the mean of the distribution of the local curvatures of the product (e.g., as illustrated in FIGS. 4A-4B). Operations of block 750 can include determining a sign of stress of SCL (e.g., tensile or compressive) and can further include determining various parameters and characteristics of the SCL, including specific material, amount of stress, thickness, and/or the like. In one example embodiment, the SCL can be made (at least partially) of silicon nitride or silicon oxide. In some embodiments, determining the characteristics of the SCL can be based on the optical inspection data and the polynomial decomposition of the profile (e.g., as obtained at block 730, as part of analysis of the optical inspection data). For example, an optimization software operating on a computing device can select a material based on the set of polynomial expansion coefficients, e.g., A₄, A₅, A₆, . . . . For example, selection of the SCL can be made based on the coefficient that determines a degree of parabolicity of the deformation, e.g., coefficient A₄. If the wafer is curved downwards (towards the back side of the wafer), A₄<0, a compressive SCL can be selected for the back side deposition. If A₄>0, a tensile SCL can be selected for the back side deposition.

At block 760, operations of method 700 can include forming the SCL on the product. In some embodiments, the SCL can be formed on a side of the exposed subset of features (e.g., as illustrated in FIG. 3H). In some embodiments, forming (e.g., depositing) the SCL can include maintaining temperature of the SCL not exceeding 180 degrees Celsius, 170 degrees Celsius, 160 degrees Celsius, 150 degrees Celsius, 140 degrees Celsius and/or the like.

At block 770, method 700 can include determining a local dose of the stress-modulation beam that reduces the width of the distribution of the local curvatures of the product (e.g., as illustrated in FIGS. 4C-4D). The stress-modulation beam can include a beam of ions, a beam of photons, and/or a beam of electrons.

In some embodiments, the local dose of the stress-modulation beam is computed based on a simulation of the stress of the product performed at least in view of (i) the deformation profile, (ii) elastic properties of the product, and (iii) a model characterizing modification of the elastic properties of the product by particles of the stress-modulation beam. In some embodiments, settings for the stress-modulation beam can include a type of particles of the stress-modulation beam, an energy of the particles of the stress-modulation beam, and/or an angle of incidence of the particles of the stress-modulation beam.

At block 780, method 700 includes irradiating the SCL with the stress-modulation beam. In some embodiments, irradiating the SCL with the stress-modulation beam includes (e.g., as disclosed in conjunction with FIGS. 3I-3K) applying, responsive to formation of a first portion of the SCL, the stress-modulation beam to the first portion of the SCL and forming a second portion of the SCL on the first portion of the SCL.

In some embodiments, method 700 can continue, at block 790, with cutting the plurality of features into a plurality of dies and can further include forming one or more die stacks, each die stack having one or more dies (e.g., as illustrated in FIG. 2H).

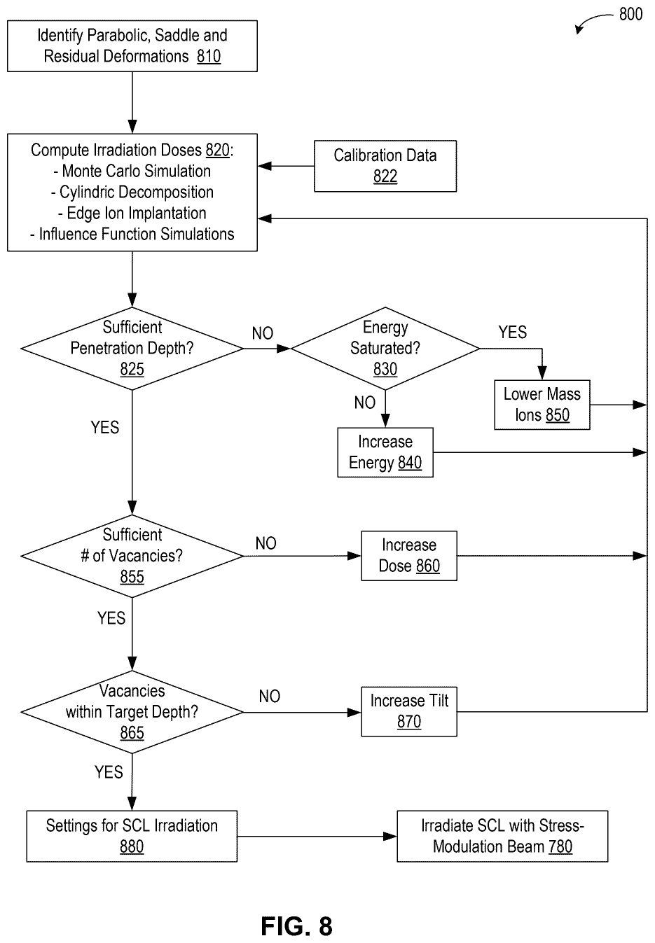

FIG. 8 is a flowchart illustrating an example method 800 of determining settings for beam irradiation, in accordance with at least one embodiment. Method 800 can be performed as part of block 770 of method 700. At block 810, method 800 can include identifying some or all of a parabolic deformation (e.g., Zernike coefficients A₄), saddle deformation (e.g., Zernike coefficients A₅, A₆), and the residual deformation (e.g., Zernike coefficients A₇, A₈ . . . ) of a wafer, e.g., using profilometry measurements.

At block 820, method 800 can continue with computing irradiation doses n(\vec{r}) for the SCL deposited on the wafer. Operations of block 820 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of h_{WF}(\vec{r}), e.g., a decomposition of a saddle shape deformation into a parabolic deformation and a cylindrical deformation.

In some embodiments, irradiation doses n(\vec{r}) can be computed (and then applied at block 880) for selected edge regions of the SCL. For example, if the axis of cylindrical deformation is the y-axis, the edge regions can be regions located within some vicinity of points x=±R, y=0, where R is the radius of the wafer. Irradiation doses n(\vec{r}) near other regions (e.g., near the center of the wafer) can be significantly lower and/or zero, in some embodiments. In some embodiments, the edge regions of the SCL have a width that is at or below 30% of a diameter of the wafer. In some embodiments, the edge regions of the SCL can be exposed to a spatially uniform dose of particles of the stress-modulation beam, a radially-varying dose of particles of the stress-modulation beam, or an azimuthally-varying dose of particles of the stress-modulation beam. In some embodiments, irradiation doses n(\vec{r}) can be spread out more uniformly across the area of the wafer, e.g., can be non-zero both near the edges and near the middle of the wafer. In some embodiments, irradiation doses n(\vec{r}) can be uniform (constant) throughout the area of the wafer while the uniformity of stress-modulation is achieved by the deposited protective pattern having spatially-varying parameters (e.g., width W, period P, thickness T, etc.).

In some embodiments, irradiation doses n(\vec{r}) can be computed using an influence function G (\vec{r};\vec{r}′), also known as the Green's function, which characterizes a response (e.g., deformation) of the wafer at a point \vec{r} of the wafer as caused by a point-like force applied at a point \vec{r}′ of the wafer. In some embodiments, the influence function G(\vec{r};\vec{r}′) can be determined from computational simulations or analytical calculations. In some embodiments, the influence function can be determined from one or more experiments, which can include performing ion implantation into a film deposited on a reference wafer. In some embodiments, a combination of multiple techniques of determining the influence function G(\vec{r};\vec{r}′) can be used.

As a way of example, the Monte Carlo simulations for a structure (e.g., wafer with films and an SCL deposited thereon) can be performed for specific materials of the structure (e.g., silicon wafer, stack of films, and/or the like) and for a specific thickness of the structure. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the SCL (e.g., a default velocity of scanning and a default scanning pattern), and the like.

In some embodiments, various techniques of irradiation dose computations can use calibration data 822 collected for actual irradiation performed for various types of the irradiation beams, energies of the irradiation beams, types and materials of structures being irradiated, angles of beam incidence on the structures, and/or the like. In some embodiments, calibration data 822 can be statistically preprocessed. For example, various measurements can be collected for multiple wafer/films/SCL materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 820 can include sampling from the stored distributions and identifying a likelihood that a target stress mitigation will be achieved with the default settings of conditions of beam irradiation of a SCL of a given type and thickness. Method 800 can include several verification operations designed to determine whether the target stress can be achieved without detrimentally affecting properties of the wafer/films. For example, at block 825, method 800 can include verifying if the penetration depth of the selected (e.g., default) type of particles is sufficient. For example, the penetration depth is to be at least a certain fraction of the thickness of the SCL, e.g., 20%, 30%, 50%, 80%, or more of that thickness. In some embodiments the penetration depth can be up to 100% of the thickness. If the energy is insufficient, method 800 can include checking, at block 830, if the irradiation beam source is capable of outputting particles of a higher energy. If higher energies are available, method 800 can continue with increasing the energy of the particles (block 840) and repeating irradiation dose computations of block 820 for the increased energy. If the maximum energy of the irradiation beam source has already been reached, method 800 can continue with replacing (at block 850) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 855, method 800 can include verifying whether the number of expected formed vacancies is sufficient. To verify sufficiency, method 800 can assess stress mitigation caused by formed vacancies. In one embodiment, method 800 can begin at some value of stress in the SCL, e.g., −3.0 GPa or some other suitable value (negative sign indicating compressive stress) and use beam irradiation to mitigate this stress towards a neutral point, 0.0 GPa at various locales of the SCL.

If the number of vacancies is insufficient, method 800 can include increasing a dose of particles (at block 860) and repeating irradiation dose computations of block 820 for the increased dose.

At block 865, method 800 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the wafer/films and affecting properties of the wafer/films. If the vacancies are to be formed at depths that exceed the target depth, method 800 can include (at block 870) increasing an angle of incidence (e.g., by tilting the irradiation beam) to keep vacancies (as well as substitution impurities) to a shallower region of the SCL.

Blocks 820-870 can be repeated multiple times until irradiation dose computations of block 820 are determined to be sufficient that the desired stress mitigation can be achieved, e.g., that the reduction in the tensile stress of the SCL is such that the deformation of the wafer is eliminated or at least reduced to an acceptable tolerance. The final settings for SCL irradiation (block 880) determined from irradiation dose computations can then be used for irradiation of the SCL with the stress-modulation beam (at block 780).

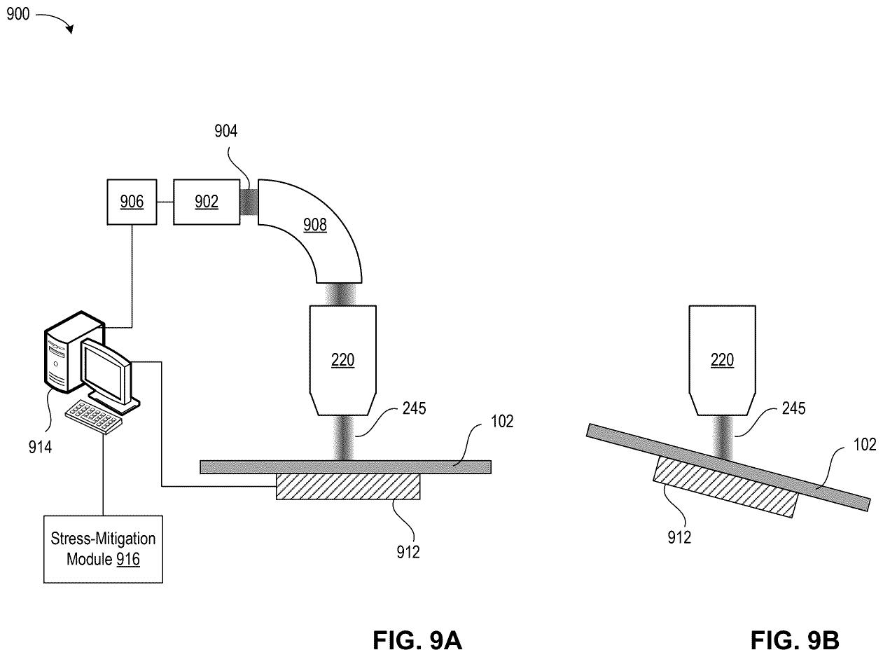

FIG. 9A illustrates schematically an irradiation system 900 capable of performing irradiation of stress compensation layers, according to at least one embodiment. Irradiation system 900 can include collimating and focusing column 220 of FIG. 2F and FIGS. 3H-3I. Irradiation system 900 can further include a beam source 902 for producing a source beam 904. Beam source 902 can include a chamber for generating ions (e.g., a plasma chamber), a light source for generating photons (e.g., a laser, laser diode, lamp, etc.), a heated filament for producing electrons, and/or any other source for the particles of a type deployed in specific stress-modulation techniques of the instant disclosure. Beam source 902 can be powered by a power element 906 and can include an extraction electrode assembly (not shown). Irradiation system 900 can include a mass spectrometer 908 (e.g., in the instances where beam source 902 produces charged particles, such as electrons or ions) and a collimating and focusing column 220. Collimating and focusing column 220 can direct stress-modulation beam 245 to substrate 202. Substrate 202 can be supported by a support stage 912. In some embodiments, support stage 912 and substrate 202 can remain stationary during irradiation of substrate 202 by stress-modulation beam 245 while components of irradiation system 900 can be repositioned relative to substrate 202. In some embodiments, irradiation system 900 can be stationary while support stage 912 can reposition substrate 202. In some embodiments, stress-modulation beam 245 can have intensity (e.g., light intensity) that is modulated by changing intensity of beam source 902 and/or placing a partially absorbing or partially reflecting material at some location between beam source 902 and substrate 202. This enables delivery of local irradiation doses n(x,y) to various locations of substrate 202. Scanning with stress-modulation beam 245 can occur along multiple directions, e.g., along x-axis and along y-axis according to any suitable predetermined pattern, e.g., back-and forth along x-axis, in a spiral pattern, and so on. In various embodiments, stress-modulation beam 245 can be scanned with a frequency of several Hz, tens of Hz, hundreds of Hz, thousands of Hz, or more.

Operations of irradiation system 900 can be controlled by a controller 914, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 914 can control operations of power element 906, support stage 912, and/or various other components and modules of irradiation system 900. Controller 914 can include a stress-modulation module 916 capable of performing simulations that determine a target intensity of stress-modulation beam 245 to be used to mitigate various wafer deformations. In some embodiments, as illustrated in FIG. 9B, support stage 912 can impart a tilt, e.g., in one or two spatial directions to substrate 202 to change an angle of incidence of stress-modulation beam 245 relative to substrate 202. In some embodiments, instead of tilting substrate 202, controller 914 can cause a tilt of stress-modulation beam 245 relative to substrate 202.

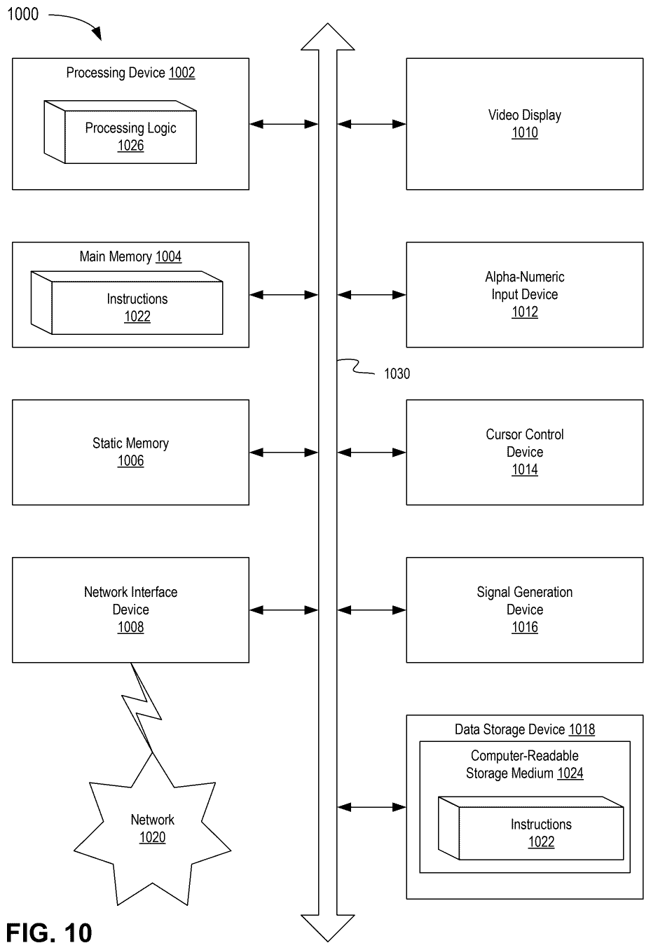

FIG. 10 depicts a block diagram of an example computer system 1000 capable of supporting operations of the present disclosure, according to at least one embodiment. In various illustrative examples, example computer system 1000 may be or include controller 914 of FIG. 9. Example computer system 1000 may be connected to other computer systems in a LAN, an intranet, an extranet, and/or the Internet. Computer system 1000 may operate in the capacity of a server in a client-server network environment. Computer system 1000 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 1000 may include a processing device 1002 (also referred to as a processor or CPU), a main memory 1004 (e.g., read-only memory (ROM), flash memory, dynamic random access memory (DRAM) such as synchronous DRAM (SDRAM), etc.), a static memory 1006 (e.g., flash memory, static random access memory (SRAM), etc.), and a secondary memory (e.g., a data storage device 1018), which may communicate with each other via a bus 1030.

Processing device 1002 represents one or more general-purpose processing devices such as a microprocessor, central processing unit, or the like. More particularly, processing device 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1002 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 1002 may include a processing logic 1026 configured to execute instructions (e.g., instructions 1022) implementing example method 700 of deploying stress-compensation layers and stress-modification beams for local die wrap correction and/or method 800 of determining settings for beam irradiation.

Example computer system 1000 may further comprise a network interface device 1008, which may be communicatively coupled to a network 1020. Example computer system 1000 may further comprise a video display 1010 (e.g., a liquid crystal display (LCD), a touch screen, or a cathode ray tube (CRT)), an alphanumeric input device 1012 (e.g., a keyboard), a cursor control device 1014 (e.g., a mouse), and an acoustic signal generation device 1016 (e.g., a speaker).

Data storage device 1018 may include a computer-readable storage medium (or, more specifically, a non-transitory computer-readable storage medium) 1024 on which is stored one or more sets of executable instructions 1022. In accordance with one or more aspects of the present disclosure, executable instructions 1022 may comprise executable instructions implementing example method 700 of deploying stress-compensation layers and stress-modification beams for local die wrap correction and/or method 800 of determining settings for beam irradiation.

Executable instructions 1022 may also reside, completely or at least partially, within main memory 1004 and/or within processing device 1002 during execution thereof by example computer system 1000, main memory 1004 and processing device 1002 also constituting computer-readable storage media. Executable instructions 1022 may further be transmitted or received over a network via network interface device 1008.

While the computer-readable storage medium 1024 is shown in FIG. 10 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
forming a product comprising a plurality of features supported by one or more substrates;
determining a deformation profile of the product;
determining, using the deformation profile, a distribution of local curvatures of the product;
forming a stress-compensation layer (SCL) on the product, one or more properties of the SCL determined to reduce a mean of the distribution of the local curvatures of the product; and
irradiating the SCL with a stress-modulation beam, a local dose of the stress-modulation beam determined to reduce a width of the distribution of the local curvatures of the product.

2. The method of claim 1, wherein the stress-modulation beam comprises at least one of: a beam of ions, a beam of photons, or a beam of electrons.

3. The method of claim 1, wherein forming the product comprises:
forming the plurality of features on a first substrate of the one or more substrates;
causing a second substrate of the one or more substrates to adhere to the plurality of features;
thinning the first substrate to expose at least a subset of features of the plurality of features;
wherein the SCL is formed on a side of the exposed subset of features.

4. The method of claim 3, wherein thinning the first substrate comprises at least one of:
grinding the first substrate,
dry etching the first substrate,
wet etching the first substrate, or
applying chemical-mechanical polishing to the first substrate.

5. The method of claim 1, wherein the plurality of features comprises:
a plurality of dynamic random-access memory (DRAM) layers, and
interconnect circuitry formed across at least some of the plurality of DRAM layers.

6. The method of claim 1, wherein the SCL comprises at least one of silicon nitride or silicon oxide.

7. The method of claim 1, further comprising:
cutting the plurality of features into a plurality of dies; and
forming one or more die stacks, each die stack comprising one or more dies of the plurality of dies.

8. The method of claim 1, wherein forming the SCL comprises:
maintaining a temperature of the SCL not exceeding 180 Celsius.

9. The method of claim 1, wherein the distribution of local curvatures of the product comprises a plurality of curvature values, each curvature value of the plurality of curvature values characterizing a degree of curvature of a respective die-size portion of the product.

10. The method of claim 1, wherein determining the deformation profile of the product comprises:
performing optical inspection of the product.

11. The method of claim 1, wherein the local dose of the stress-modulation beam is computed based on a simulation of a stress of the product performed at least in view of:
the deformation profile,
elastic properties of the product, and
a model characterizing modification of the elastic properties of the product by particles of the stress-modulation beam.

12. The method of claim 1, wherein settings for the stress-modulation beam comprise one or more of:
a type of particles of the stress-modulation beam,
an energy of the particles of the stress-modulation beam, or
an angle of incidence of the particles of the stress-modulation beam.

13. The method of claim 1, wherein irradiating the SCL with the stress-modulation beam comprises:
applying, responsive to formation of a first portion of the SCL, the stress-modulation beam to the first portion of the SCL; and
forming a second portion of the SCL on the first portion of the SCL.

14. A system comprising:
a memory device; and
a processing device communicatively coupled to the memory device, wherein the processing device causes performance of operations comprising:
forming a product comprising a plurality of features supported by one or more substrates;
determining a deformation profile of the product;
determining, using the deformation profile, a distribution of local curvatures of the product;
forming a stress-compensation layer (SCL) on the product, one or more properties of the SCL determined to reduce a mean of the distribution of the local curvatures of the product; and
irradiating the SCL with a stress-modulation beam, a local dose of the stress-modulation beam determined to reduce a width of the distribution of the local curvatures of the product.

15. The system of claim 14, wherein the plurality of features comprises:
a plurality of dynamic random-access memory (DRAM) layers, and
interconnect circuitry formed across at least some of the DRAM layers.

16. The system of claim 14, wherein the SCL comprises at least one of silicon nitride or silicon oxide and wherein forming the SCL comprises:
maintaining a temperature of the SCL not exceeding 180 Celsius.

17. The system of claim 14, wherein the distribution of local curvatures of the product comprises a plurality of curvature values, each curvature value of the plurality of curvature values characterizing a degree of curvature of a respective die-size portion of the product.

18. The system of claim 14, wherein the local dose of the stress-modulation beam is computed based on a simulation of a stress of the product performed at least in view of:
the deformation profile,
elastic properties of the product, and
a model characterizing modification of the elastic properties of the product by particles of the stress-modulation beam.

19. The system of claim 14, wherein irradiating the SCL with the stress-modulation beam comprises:
applying, responsive to formation of a first portion of the SCL, the stress-modulation beam to the first portion of the SCL; and
forming a second portion of the SCL on the first portion of the SCL.

20. A semiconductor manufacturing system comprising one or more processing chambers, the semiconductor manufacturing system to:
form a product comprising a plurality of features supported by one or more substrates;
determine a deformation profile of the product;
determine, using the deformation profile, a distribution of local curvatures of the product;
form a stress-compensation layer (SCL) on the product, one or more properties of the SCL determined to reduce a mean of the distribution of the local curvatures of the product; and
irradiate the SCL with a stress-modulation beam, a local dose of the stress-modulation beam determined to reduce a width of the distribution of the local curvatures of the product.
